(19) United States
(12) Patent Application Publication
(10) Pub. No.: US 2016/0104621 A1
(43) Pub. Date: Apr. 14, 2016

(54) SEMICONDUCTOR DEVICE HAVING COMMON CONTACT AND GATE PROPERTIES

(71) Applicant: GLOBALFOUNDRIES Inc., Grand Cayman (KY)

(72) Inventor: Hui ZANG, Guilderland, NY (US)

(73) Assignee: GLOBALFOUNDRIES INC., Grand Cayman (KY)

(21) Appl. No.: 14/512,009

(22) Filed: Oct. 10, 2014

(51) Int. Cl. H01L 21/283; H01L 21/28; H01L 29/417

(52) U.S. Cl. CPC H01L 21/283; H01L 29/41775; H01L 21/28008

(57) ABSTRACT

In one aspect there is set forth herein a semiconductor device wherein a contact conductive layer and a gate conductive layer include a common conductive material. In one aspect a source/drain region contact conductive layer of an nFET, and a gate conductive layer of a gate of the nFET can be fabricated to include an n material. In one aspect a source/drain region contact conductive layer of a pFET, and a gate conductive layer of the pFET can be fabricated to include an p material.

### FIELD OF THE INVENTION

The present invention relates to semiconductor devices, and more particularly, to field effect transistor semiconductor devices.

### BACKGROUND OF THE INVENTION

Different semiconductor devices may be fabricated to have one or more different device characteristics, such as switching speed, leakage power consumption, etc. Multiple different designs may each provide optimization of one or more of these characteristics for devices intended to perform specific functions. For instance, one design may increase switching speed for devices providing computational logic functions, and another design may decrease power consumption for devices providing memory storage functions. A system using multiple discrete devices optimized for different functions presents challenges in terms of system complexity, system footprint and cost.

Optimization challenges are pronounced with continued miniaturization of semiconductor devices.

A semiconductor device can be provided by a discrete device, e.g. a field effect transistor (FET), a diode, and resistor. A semiconductor device can be provided by structure, e.g. a wafer, a die, an integrated circuit having one or a plurality of discrete semiconductor devices.

One parameter affecting a performance of a semiconductor device is contact resistance. A contact of a field effect transistor (FET) can include one or more conductive material layer formed over a conductive material layer defining a source/drain region. In typical formation a metal layer, e.g. of Tungsten (W) or Aluminum (Al) can be formed over a barrier formation adjacent to the source drain/region. The barrier formation can include one or more conductive layer. The barrier formation can be provided to reduce diffusion effects resulting from the metal layer being in proximity to the source/drain region.

### BRIEF DESCRIPTION

In one aspect there is set forth herein a semiconductor device wherein a contact conductive layer and a gate conductive layer include a common conductive material. In one aspect a source/drain region contact conductive layer of an nFET and a gate conductive layer of a gate of the nFET can be fabricated to include an n material. In one aspect a source/drain region contact conductive layer of a pFET, and a gate conductive layer of the pFET can be fabricated to include a p material. In one aspect, an n material can include a lower work function than a p material.

### BRIEF DESCRIPTION OF THE SEVERAL VIEWS OF THE DRAWINGS

One or more aspects as set forth herein are particularly pointed out and distinctly claimed as examples in the claims at the conclusion of the specification. The foregoing and other objects, features, and advantages of the invention are apparent from the following detailed description taken in conjunction with the accompanying drawings in which:

FIGS. 1 through 9 illustrate a semiconductor device in partial states of fabrication;

FIG. 10 illustrates a semiconductor device including fabricated FETs, the semiconductor device having labeled Region A configured as an nFET region, and labeled Region B configured as a pFET region;

FIG. 11 illustrates a semiconductor device in a partial state of fabrication;

FIG. 12 illustrates a semiconductor device including fabricated FETs, the semiconductor device having labeled Region A configured as a pFET region and labeled Region B configured as an nFET region;

FIGS. 13-22 illustrate a semiconductor device in a partial state of fabrication;

FIG. 23 illustrates a semiconductor device including fabricated FETs, the semiconductor device having a region of a first polarity (nFET or pFET) with a contact conductive layer and a gate conductive layer of a common conductive material, and a region of a second polarity opposite the first polarity (nFET or pFET) with a contact conductive layer of a material absent from a gate.

### DETAILED DESCRIPTION

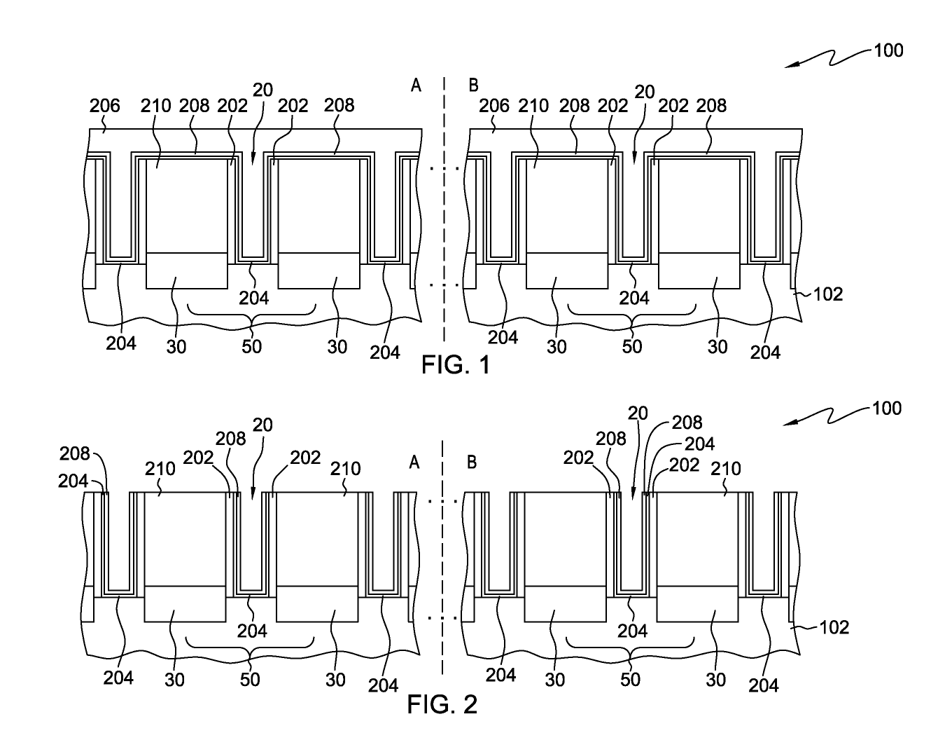

In reference to FIGS. 1-23 there is set forth a method for fabricating a semiconductor device wherein a contact conductive layer and a gate conductive layer of a FET can include a common conductive material. The contact conductive layer and the gate conductive layer can be of a common deposition layer formed by commonly depositing the contact conductive layer and the gate conductive layer during a common deposition process. The contact conductive layer and the gate conductive layer can be of a common thickness. In one aspect, a source/drain contact conductive layer and a gate conductive layer of an pFET can be fabricated to include a p material. In one aspect a source/drain contact conductive layer and a gate conductive layer of an nFET can be fabricated to include an n material. A deposition layer as set forth herein can be a layer that is commonly deposited by a common deposition process. A deposition layer can include a common thickness throughout the layer.

The work function of a material is an electrical property of a conductor that describes the minimum energy required to remove an electron from the material. A work function layer of a gate structure, therefore, is a material layer that directly impacts the threshold voltage.

In the development of methods and apparatus herein p materials and n materials were identified. A p material can be a material compatible for use with pFET structures. An n material can be a material compatible for use with nFET structures. A p material can have a higher work function value than an n material. In one example a p material can have a work function of greater than 4.5 eV and an n material can have a work function of less than 4.5 eV. In one example a p material can have a work function of 5.2 eV and an n material can have a work function of 4.05 eV.

A p material can be a material well adapted for use in tuning a voltage threshold of a gate of a pFET (a FET having a p channel and an n well) to a lower value. It was determined that TiN is a p material. For pFETs larger depositions of TiN proximate a channel region can be provided to yield lower voltage thresholds. Accordingly, for example, super low voltage threshold (SLVT) pFET FETs 50 can be provided by including relatively thick layers of TiN closer to a channel region, e.g. adjacent to a gate dielectric layer.

An n material is a material well adapted for use in tuning a voltage threshold of a gate of an nFET (a FET having an n channel and a p well) to a lower value. It was determined that TiAlC is an n material. As such, it was determined that for nFETs, larger depositions of TiAlC proximate a channel region can be provided to yield lower voltage thresholds. Accordingly, for example, super low voltage threshold (SLVT) nFET FETs 50 can be provided by including relatively thick layers of TiAlC closer to a channel region, e.g. adjacent to a gate dielectric layer.

In the development of methods and apparatus herein it was observed that p materials are well adapted for use as contact forming materials in pFETs. It was observed that a p material when used as a contact layer with a pFET source/drain produces a lower energy Schottky barrier than is produced by an n material. It was observed further that an n material, when used as a contact layer with an nFET source/drain produces a lower energy Schottky barrier than a p material. Use of a p material for a pFET source/drain contact can reduce a contact resistance of the contact. Use of an n material for an nFET source/drain contact can reduce a contact resistance of the contact.

With use of methods herein, a FET can be provided to include a contact having a contact conductive layer and a gate having a gate conductive layer, wherein the contact conductive layer and the gate conductive layer are of a common material. The contact conductive layer and the gate conductive layer can be of a common deposition layer (can be deposited with a common deposition process). The contact conductive layer and the gate conductive layer can be of common thickness.

In one aspect of a method, a semiconductor device can be fabricated having a pFET and an nFET, wherein the pFET can include a contact conductive layer and a gate conductive layer of a first common material, the contact conductive layer and a gate conductive layer provided in a common deposition layer, and wherein the nFET can include a contact conductive layer and a gate conductive layer of a second common material, the contact conductive layer and a gate conductive layer provided in a common deposition layer.

Referring to FIG. 1, FIG. 1 shows a semiconductor device 100 in a partial state of fabrication. Semiconductor device 100 includes a plurality of gate areas defined by gates 20 (shown in a partially fabricated state in FIG. 1) and a pair of source/drain regions 30 adjacent each gate 20. A FET 50 can include a gate 20 and a pair of adjacent source/drain regions 30. Each gate 20 can include a pair of spacers 202 as well as a gate dielectric layer 204. Dielectric layer 204 can be a high k layer in one embodiment. In the partial state of fabrication shown in FIG. 1 each gate 20 can include a polysilicon layer 206. Polysilicon layer 206 can be layered over a sacrificial conductive layer 208. With further reference to the semiconductor device 100 shown and the partial fabrication view of FIG. 1, source/drain regions 30 in one embodiment can be raised source/drain regions that can be raised relative to a top elevation of substrate 102 using epitaxial growth formation processes.

In one embodiment, substrate 102 can be provided by, e.g., a fin of a substrate of a semiconductor structure having a FinFet architecture or a nanowire of a substrate of a semiconductor structure having a nanowire architecture. In another embodiment, substrate 102 can be provided by a substrate of a semiconductor structure having a planar architecture. For example, substrate 102 can be a bulk substrate of semiconductor structure having a bulk architecture. In another embodiment, substrate 102 can be provided by, e.g., a top silicon layer of a semiconductor structure in accordance with a Silicon on Insulator (SOI) architecture. Substrate 102 can be formed, e.g., Si or Ge.

Semiconductor device 100 as shown in FIG. 1 can be divided into two regions A, and B, separated as indicated by the vertically extended-borderline shown throughout the views. In one embodiment, Region A of semiconductor device 100 can be a pFET region and Region B can an nFET region. In one embodiment Region A of semiconductor device 100 can be an nFET region and Region B can be a pFET region. A pFET region can include FET devices having p channels and p-type source/drain regions 30. nFET regions can include nFETs having n channels and n-type source/drain regions 30.

Referring to FIG. 2, FIG. 2 illustrates the semiconductor device 100 as shown in FIG. 1 after being subject to an etching step for removal of polysilicon layer 206.

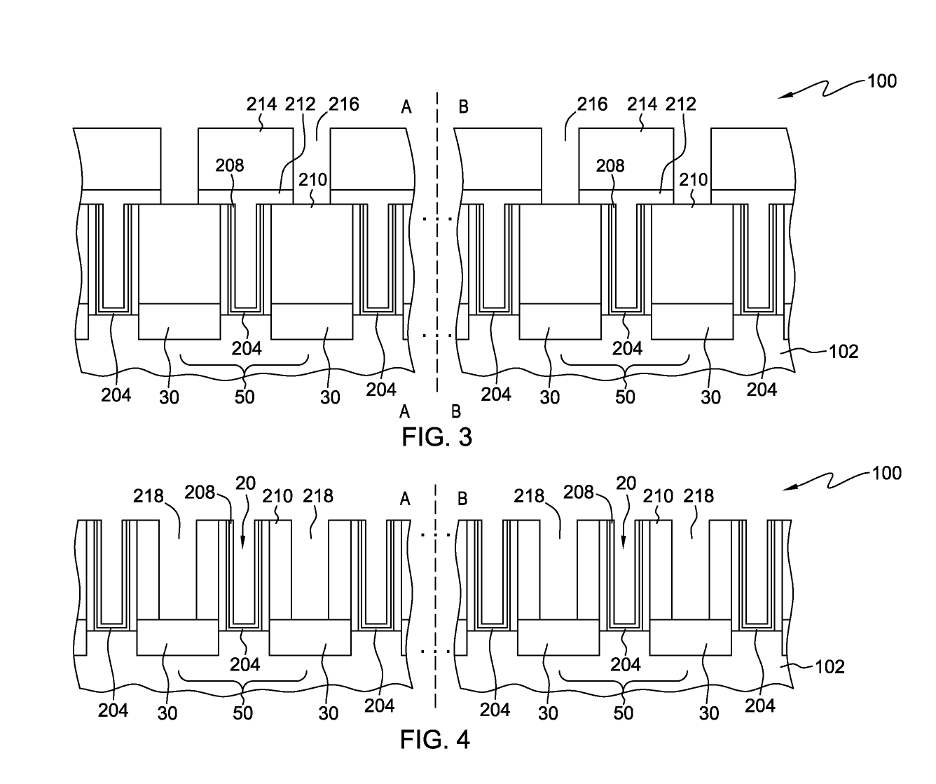

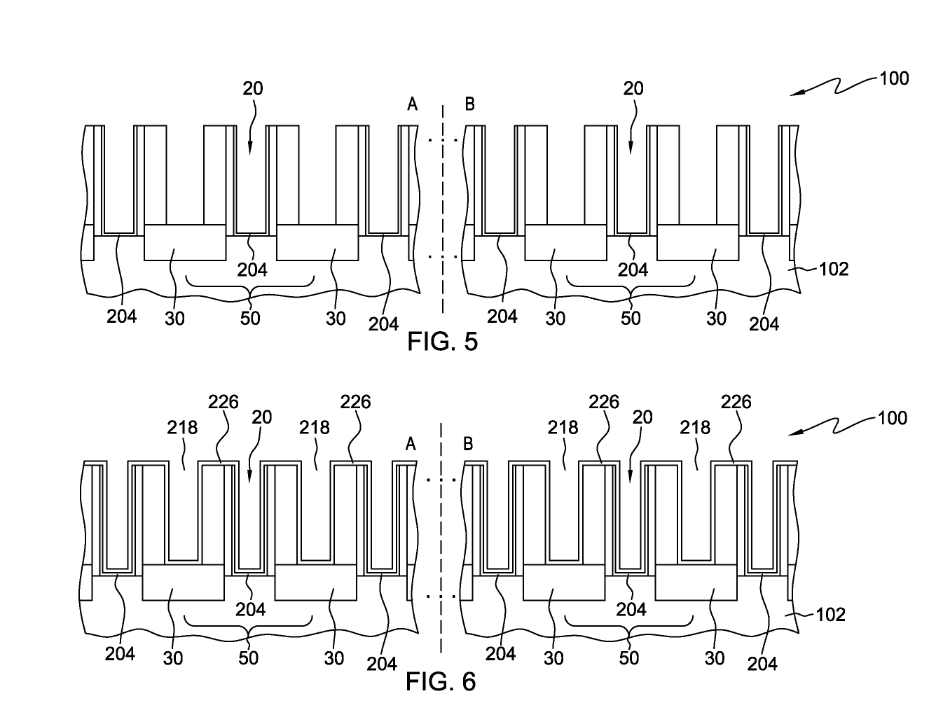

Referring to FIG. 3, FIG. 3 illustrates the semiconductor device 100 as shown in FIG. 2 after application of a mask structure for patterning of contact holes 218 (FIG. 4). The mask structure as shown in FIG. 3 can include an Organic Planarization Layer (OPL) 212 and a resist layer 214. The mask structure including layers 212, 214 can be subject to patterning utilizing an auxiliary mask layer (not shown) for providing of pattern voids 216 as shown in FIG. 3. With voids 216 defined as shown in FIG. 3, the semiconductor device 100 can be subject to etching for removal of material from oxide layer 210 to define contact holes 218 as shown in FIG. 4.

Referring to FIG. 4, FIG. 4 shows the semiconductor device 100 as shown in FIG. 3 after being subject to etching for removal of material from oxide layer 210.

Referring to FIG. 5, FIG. 5 illustrates the semiconductor device 100 as shown in the embodiment of FIG. 4 after being subject to etching for removal of sacrificial conductive layer 208. Sacrificial conductive layer 208 can be provided for increased reliability of one or more conductive layer replacing sacrificial conductive layer 208.

Referring to FIG. 6, FIG. 6 illustrates the semiconductor device 100 as shown in FIG. 5 with one or more n material layer being commonly deposited to a common thickness and with a common deposition process over each of Region A and Region B of semiconductor device 100. In the embodiment as shown in FIG. 6 the one or more n material layer can include n material layer 226. Still referring to FIG. 6, the one or more n material layer can be deposited within each gate 20 and within each defined contact hole 218 throughout Region A and Region B. Referring to semiconductor device 100 in the partial state of fabrication shown in FIG. 6, n material layer 226 can be deposited in Region A and, as will be set forth in detail herein, can be sacrificially deposited in Region B in one embodiment. Within Region A, n material layer 226 can define a contact conductive layer of a contact for each source/drain region 30 of Region A. Within Region A, n material layer 226 can define a gate conductive layer for each gate 20 of Region A.

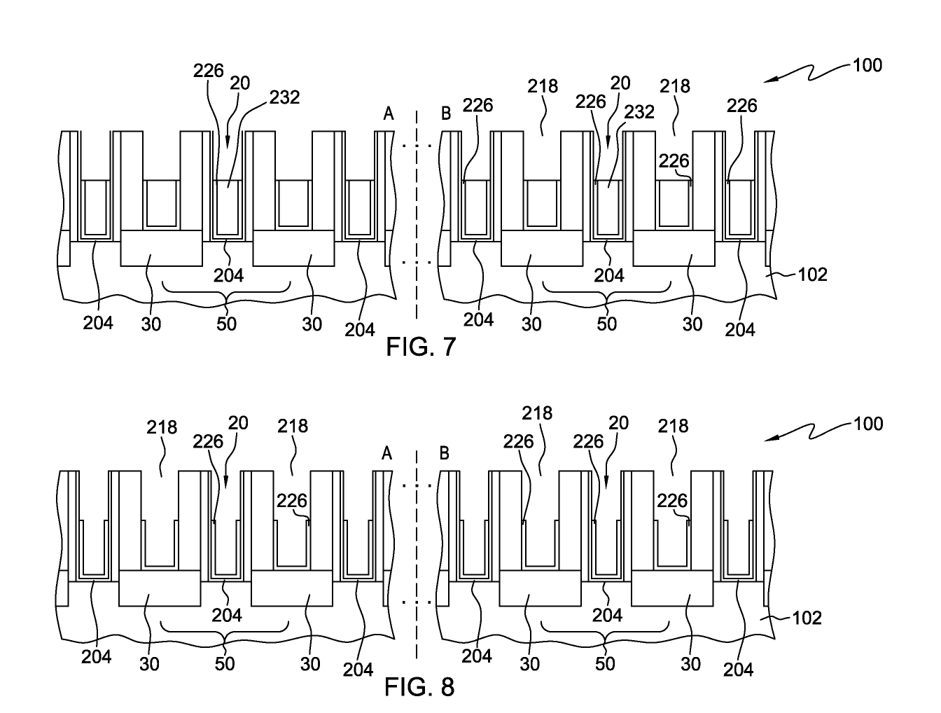

Referring to FIG. 7, FIG. 7 illustrates semiconductor device 100 in a state of fabrication after semiconductor device 100 is subject to deposition for depositing of OPL layer 232 and then chamfering to reduce an elevation of OPL layer 232 as well as n material layer 226 formed as a deposition layer. Referring to FIG. 8, FIG. 8 illustrates semiconductor device 100 as shown in FIG. 7 after etching for removal of OPL layer 232. OPL layer 232 can be regarded to be a mask layer.

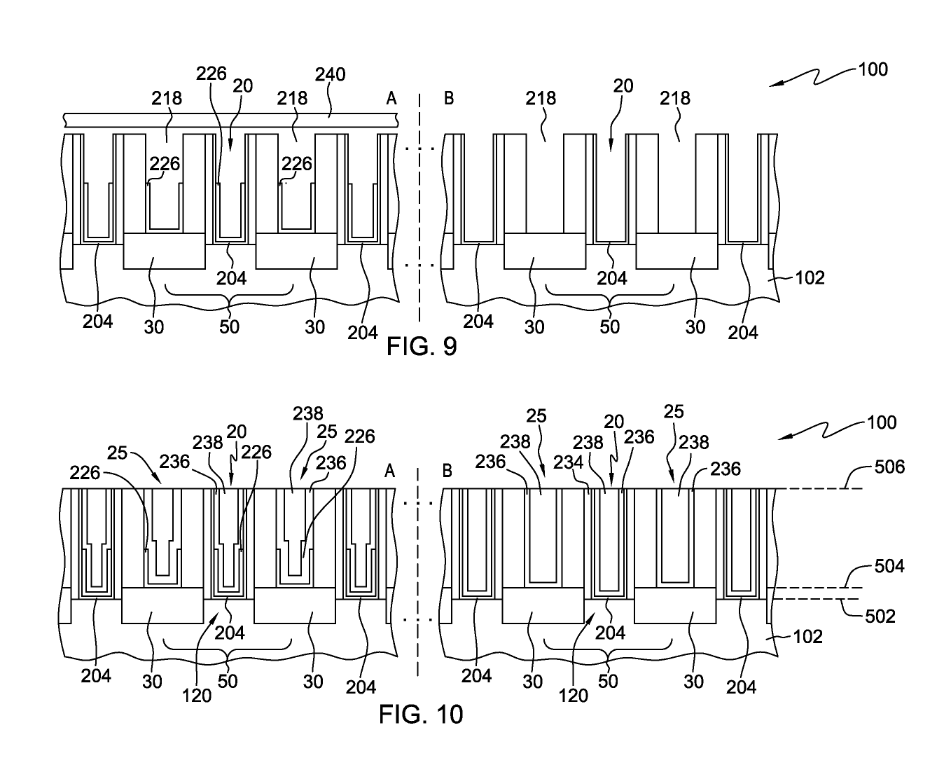

Referring to FIGS. 9 and 10, FIGS. 9 and 10 illustrate processes for differentiation between a pFET region (Region B in the specific embodiment) and an nFET region (Region A in the specific embodiment). Referring to FIG. 9, a mask layer 240 can be applied to cover Region A leaving Region B open. With mask layer 240 applied, Region B can be subject to etching for removal of n material layer 226 from Region B leaving Region B in the partial state of fabrication of FIG. 9 absent of gate conductive layers.

Referring to FIG. 10, FIG. 10 illustrates semiconductor device 100 as shown in the state of fabrication in FIG. 9 with one or more p material layers deposited over each of Region A and Region B. The one or more p material layers can include e.g., a single layer or a plurality of layers. In the embodiment as shown in FIG. 10, a p material can include p material layer 236 forming a deposition layer. Further as shown in FIG. 10, a capping layer 238 can be deposited over p material layer 236. p material layer 236 and capping layer 238 can be deposited over each gate 20 and over each contact hole 218 of Region A and Region B so that the p material layers 236 and capping layer 238 fill each illustrated contact hole 218 (shown in FIGS. 4-9) and each gate 20 of Region A and Region B. Within Region A and Region B, p material layer 236 can define a contact conductive layer for and of a contact for each source/drain region 30 of Region A and Region B. Within Region A and Region B, p material layer 236 can define a gate conductive layer for and of each gate 20 of Region A and Region B.

In the fabricated FETs 50 of FIG. 10, gates 20 of the defined nFET Region A can include gate conductive layers provided by p material layer 236 layered over n material layer 226. In the defined pFET Region B of FIG. 10, gates 20 can have deposited therein one or more gate conductive layer including p material layer 236 and can be absent of any n material layer. In the fabricated FETs 50 of FIG. 10, contacts 25 of the defined nFET Region A can include contact conductive layers provided by p material layer 236 layered over n material layer 226 (which can be adjacent source/drain region 30). In the defined pFET Region B of FIG. 10, contacts 25 for source/drain regions 30 can have one or more contact conductive layer including p material layer 236 (which can be adjacent source/drain region 30) and can be absent of any n material layer.

In reference to FIGS. 1-10, a method is described wherein an nFET region is defined in Region A and a pFET region is defined in Region B of semiconductor device 100, and in accordance with the method an n material layer can be deposited prior to depositing a p material.

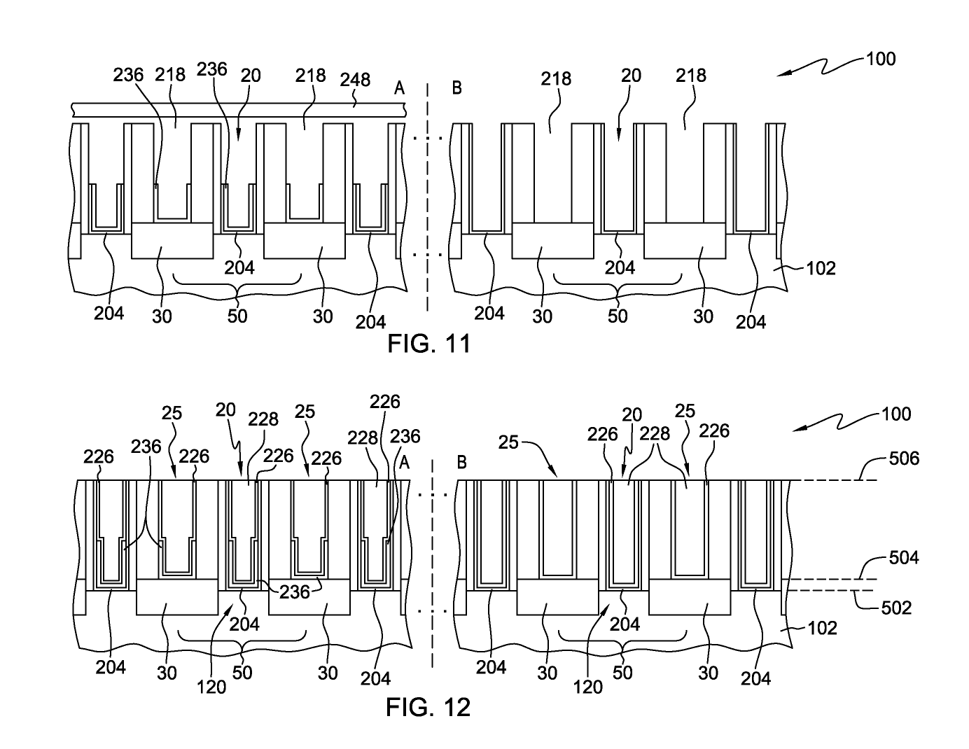

A method alternative to the method described with reference to FIG. 1-10 is illustrated with reference to FIGS. 11 and 12. Referring to the method illustrated with reference to FIGS. 11 and 12, Region A can be defined as a pFET region, Region B can be defined as an nFET region, and a process can be performed so that one or more p material layer can be deposited prior to depositing of an n material layer.

Referring to FIG. 11, FIG. 11 illustrates a semiconductor device 100 in a state of fabrication after p material layer 236 forming a deposition layer is deposited within each gate 20 and within each contact hole 218 of Region A and Region B of semiconductor device 100 and then is selectively removed from Region B. Referring to FIG. 11, p material layer 236 within Region B can be etched after application of mask layer 248 which can be adapted to cover Region A and can further be adapted to leave Region B open. Prior to the stage of fabrication illustrated in reference to FIG. 11, p material layer 236 can be deposited within each gate 20 and within each contact hole 218 of Region A and Region B in the manner of the depositing of n material layer 226 described with reference to FIG. 5-8.

Referring to FIG. 12, FIG. 12 illustrates the semiconductor device 100 as shown in FIG. 11 after application of one or more n material layer. FIG. 12 illustrates the semiconductor device 100 in a state of fabrication after n material layer 226 forming a deposition layer is deposited in each gate 20 and each contact hole 218 of Region A and Region B. A capping layer 228 can also be deposited within each gate 20 and within each contact hole 218 in Region A and Region B as shown in FIG. 12.

Referring to the fabricated semiconductor device 100 as shown in FIG. 12, gates 20 of the defined pFET Region A can include gate conductive layers provided by n material layer 226 layered over p material layer 236. In the defined nFET Region B of FIG. 12, gates 20 can have deposited therein one or more gate conductive layer including n material layer 226 and can be absent of any p material layer. In the fabricated FETs 50 of FIG. 12, contacts 25 of the defined pFET Region A can include contact conductive layers provided by n material layer 226 layered over p material layer 236. In the defined nFET Region B of FIG. 12, contacts 25 for source/drain regions 30 can have one or more contact conductive layer including n material layer 226 and can be absent of any p material layer.

Referring to Region A of the embodiment of FIG. 10, a contact conductive layer provided by n material layer 226 can be of a common material with a gate conductive layer provided by n material layer 226. The contact conductive layer provided by n material layer 226 can be adjacent to source/drain region 30. The gate conductive layer provided by n material layer 226 can be adjacent to and above gate dielectric layer 204. Gate dielectric layer 204 can be adjacent to and above channel region 120 defined within substrate 102.

Referring to Region B of the embodiment of FIG. 10, a contact conductive layer provided by p material layer 236 can be of a common material with a gate conductive layer provided by p material layer 236. The contact conductive layer provided by p material layer 236 can be adjacent to source/drain region 30. The gate conductive layer provided by p material layer 236 can be adjacent to and above gate dielectric layer 204. Gate dielectric layer 204 can be adjacent to and above channel region 120 defined within substrate 102.

Referring to Region A of the embodiment of FIG. 12, a contact conductive layer provided by p material layer 236 can be of a common material with a gate conductive layer provided by p material layer 236. The contact conductive layer provided by p material layer 236 can be adjacent to source/drain region 30. The gate conductive layer provided by p material layer 236 can be adjacent to and above gate dielectric layer 204. Gate dielectric layer 204 can be adjacent to and above channel region 120 defined within substrate 102.

Referring to Region B of the embodiment of FIG. 12, a contact conductive layer provided by n material layer 226 can be of a common material with a gate conductive layer provided by n material layer 226. The contact conductive layer provided by n material layer can be adjacent to source/drain region 30. The gate conductive layer provided by n material layer 226 can be adjacent to and above gate dielectric layer 204. Gate dielectric layer 204 can be adjacent to and above channel region 120 defined within substrate 102.

In the method set forth in reference to FIGS. 1-12 each defined FET 50 within Region A and Region B of semiconductor device 100 can include a gate conductive layer of gate 20 and a contact conductive layer of an adjacent source/drain region 30 of a common material, e.g., a common n material or a common p material. In the fabricated FETs shown in FIG. 10 and FIG. 12 material layers filling contact holes 218 define contacts 25.

In the embodiments of methods set forth to reference to FIGS. 13-23 one of Region A and Region B can be fabricated to include a contact conductive layer and gate conductive layer of a common material and a remaining of Region A and Region B can include a contact conductive layer for a source/drain region adjacent to a gate that is not of a material in common with a gate conductive layer. The embodiments and methods as set forth in reference to FIGS. 13-23 add flexibility, e.g., in the case it is desired to provide asymmetrical gates and contacts for only one of nFETS or pFETS of a semiconductor device 100.

Semiconductor device 100 as shown in the partial state of fabrication of FIG. 13 can have the structure as shown in reference to semiconductor device 100 in the partial state of fabrication as shown in FIG. 1.

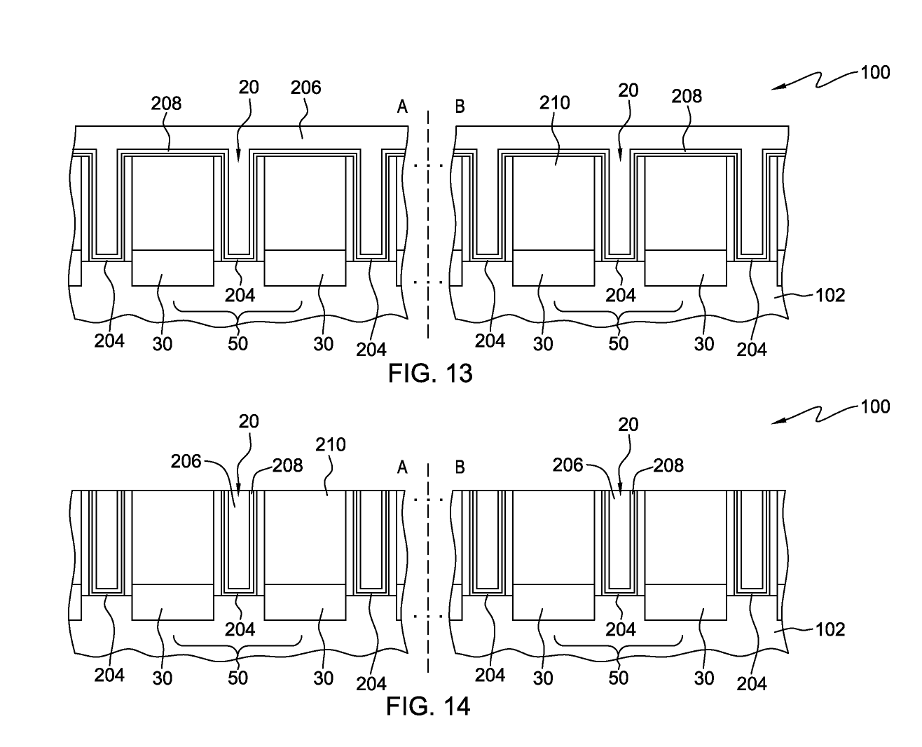

Referring to FIG. 14, FIG. 14 shows the semiconductor device 100 in the state of fabrication as shown in FIG. 13 after being subject to planarization so that polysilicon layer 206 can be planarized and removed above an elevation of gates 20 in Region A and Region B.

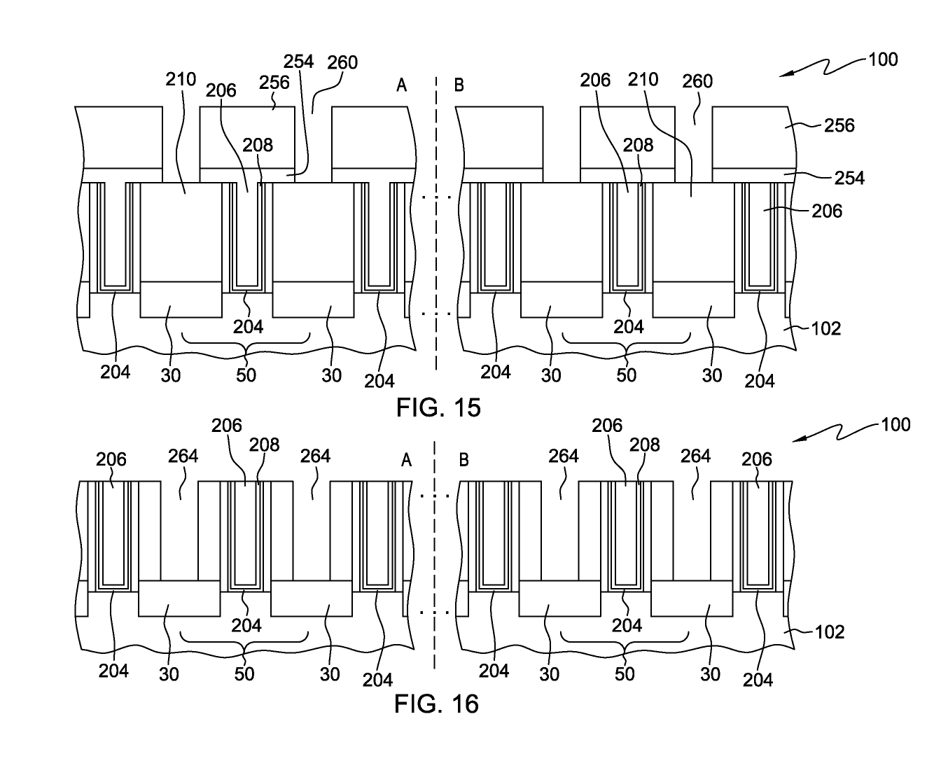

Referring to FIG. 15, FIG. 15 illustrates semiconductor device 100 with a mask structure applied wherein the mask structure is adapted for formation of contact holes. The mask as shown in FIG. 15 can include OPL layer 254 and resist layer 256 and can include voids 260 for the formation of contact holes 264 (FIG. 16) wherein the voids 260 are formed using an auxiliary mask (not shown).

Referring to FIG. 16, FIG. 16 illustrates the semiconductor device 100 in the state of fabrication shown in FIG. 15 after semiconductor device 100 is subject to etching for removal of oxide layer 210 to define contact holes 264 and further after removal of the mask structure including layers 254 and 256.

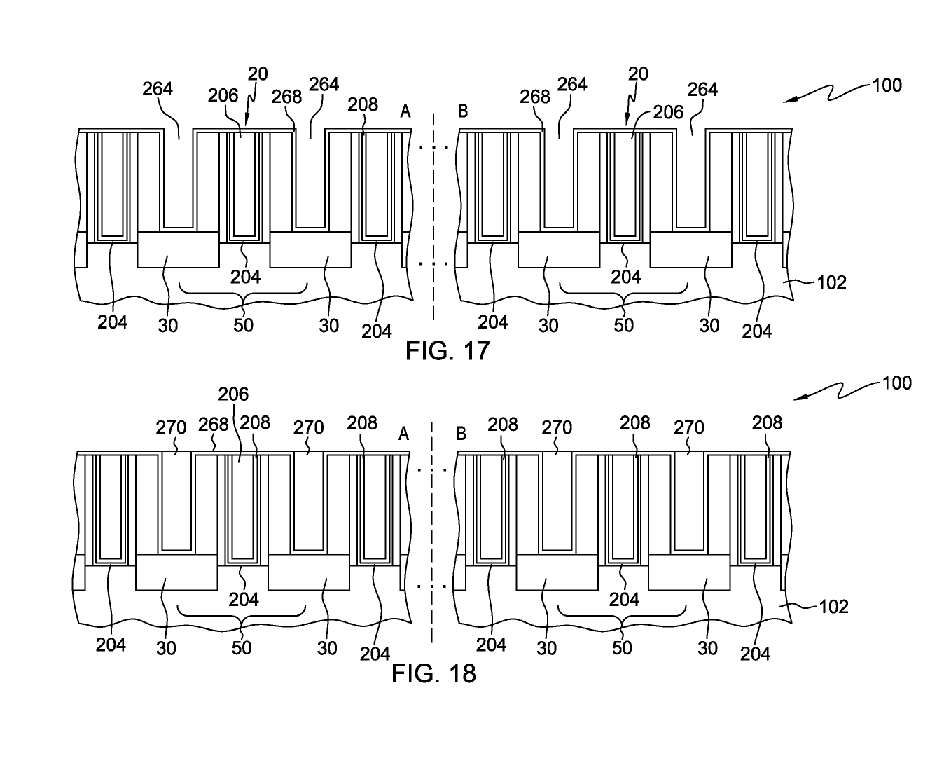

Referring to FIG. 17, FIG. 17 illustrates the semiconductor device 100 in the state of fabrication shown in FIG. 16 after deposition of contact conductive layer 268. The deposition of contact conductive layer 268 as shown in FIG. 17 can be performed prior to removal of polysilicon layer 206 from gates 20. Accordingly, a deposition of contact conductive layer 268 as shown in FIG. 17 can be selectively made within contact holes 264 but not within gates 20.

Referring to FIG. 18, FIG. 18 illustrates the semiconductor device 100 in the state of fabrication as shown in FIG. 17 after deposition of OPL material layer 270 within contact holes 264 (as shown in FIG. 17). With OPL material layer 270 deposited within contact holes 264, etching of contact conductive layer 268 can result in removal of contact conductive layer 268 except in the areas of contact holes 264. OPL layer 270 can be regarded as a mask layer.

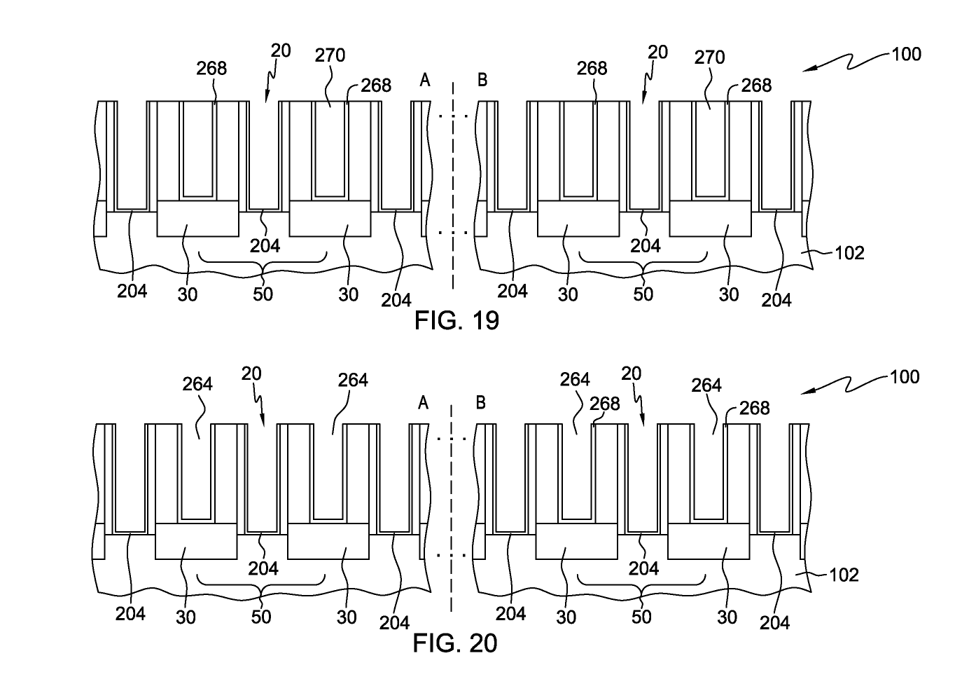

Referring to FIG. 19, FIG. 19 illustrates the semiconductor device 100 in the state of fabrication as shown in FIG. 18 after being subject to etching. With etching performed in the manner depicted in FIG. 19, contact conductive layer 268 can be removed from all areas of Region A and Region B except for in contact holes 264 which can be protected by the presence of OPL layer 270. Also removed with the etching step depicted in FIG. 19 can be polysilicon gate layer 206 and sacrificial conductive layer 208.

Referring to FIG. 20, FIG. 20 illustrates the semiconductor device 100 in the partial state of fabrication as shown in FIG. 19 after being subject to further etching for removal of OPL layer 270. With OPL layer 270 removed, contact holes 264 can be reopened.

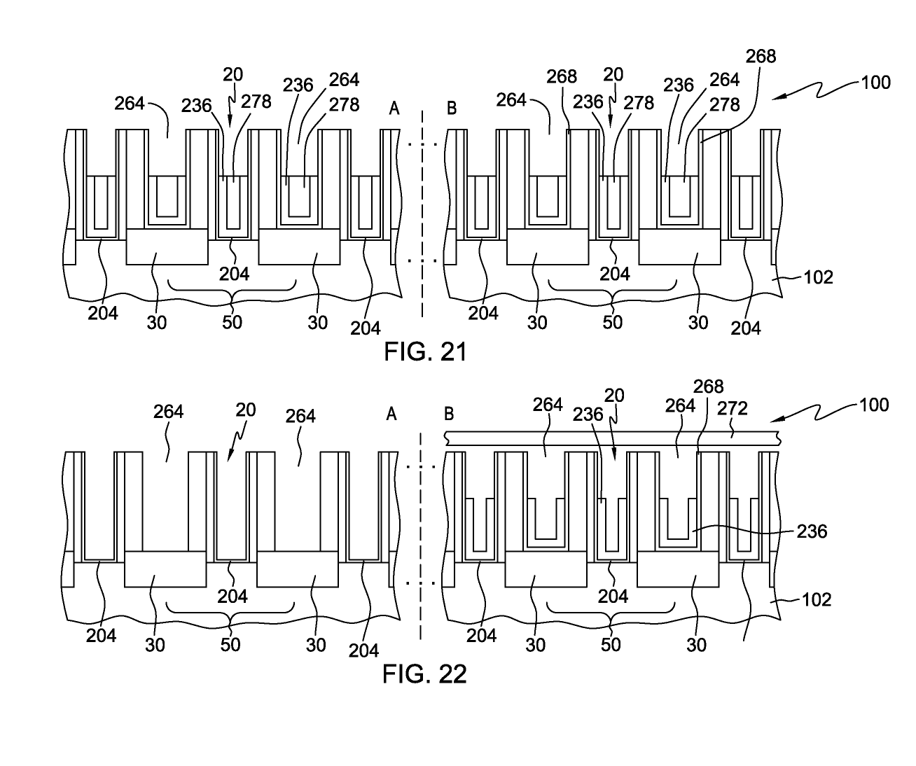

Referring to FIG. 21, FIG. 21 illustrates the semiconductor device 100 in the state of fabrication as shown in FIG. 20, after being subject to deposition for depositing of p material layer 236 forming a deposition layer and OPL layer 278 forming a deposition layer. The depositing of p material layer 236 and OPL layer 278 can be within each gate 20 and within each contact hole 264 of semiconductor device 100 throughout Region A and B. Material layer 236 and OPL layer 278 can initially fill gate 20 to a top elevation of gate 20 and then can be chamfered to provide the state illustrated in FIG. 21. OPL layer 278 can then be removed.

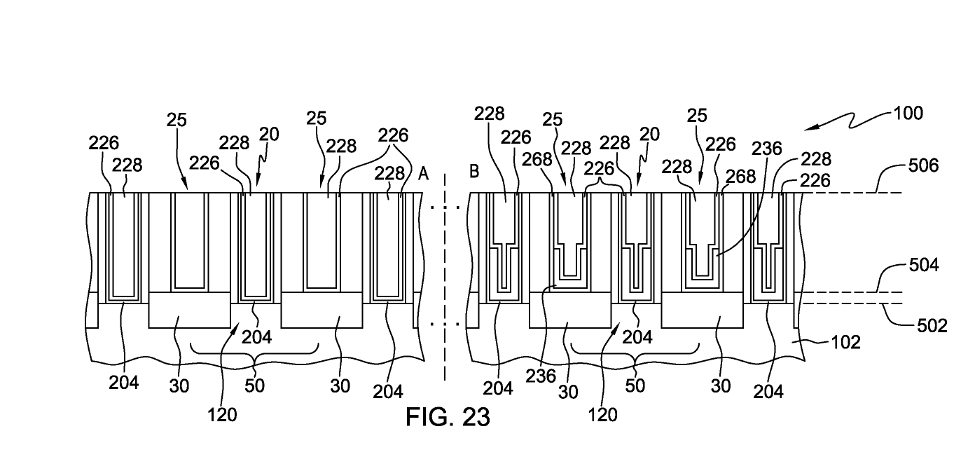

Referring to FIG. 22, FIG. 22 illustrates semiconductor device 100 in the state of fabrication as shown in FIG. 21 after removal of OPL layer 278 application of mask layer 272 which can include an open area to allow removal of material from region A, and which can cover Region B. With mask layer 272 applied, Region A can be subject to etching and as a result of an etching process the p material layer 236 can be removed from each gate 20 and each contact hole 264 of region A.

Referring to FIG. 23, FIG. 23 illustrates semiconductor device 100 in the partial state of fabrication as shown in FIG. 22 after deposition of n material layer 226 forming a deposition layer and capping layer 228 forming a deposition layer. The deposition of n material layer 226 and capping layer 228 can be throughout each gate 20 and each contact hole 264 for each of Region A and Region B.

Within Region B of the embodiment of FIG. 23, contact conductive layer 268 can define a contact conductive layer of a contact for each source/drain region 30 within Region B. Contact conductive layer 268 can be of a material different from a material of n material layer 226 and p material layer 236. Within Region B of the embodiment of FIG. 23, p material layer 236 can define a contact conductive layer of a contact for each source/drain region 30 of Region B. Within Region B, p material layer 236 can define a gate conductive layer for each gate 20 of Region B. Within gates 20 of Region B, p material layer 236 can be adjacent to and above gate dielectric layer 204 (which gate dielectric layer 204 can be adjacent to and above channel region 120 defined in substrate 102). Within Region A and Region B of the embodiment of FIG. 23, n material layer 226 can define a contact conductive layer for and of a contact for each source/drain region 30 of Region A and Region B. Within Region A and Region B, n material layer 226 can define a gate conductive layer for and of each gate 20 of Region A and Region B.

Referring to Region A defined as an nFET region in the fabricated semiconductor device 100 of FIG. 23, Region A as shown in FIG. 23 can include a contact conductive layer and gate conductive layer of a common material. Referring to Region A of the embodiment of FIG. 23, n material layer 226 can be deposited in both of gate 20 (adjacent to gate dielectric layer 204) and in contact hole 264 (adjacent to source/drain region 30). Referring to Region B of the fabricated semiconductor device of FIG. 23, Region B as shown in FIG. 23 can be a pFET region and can include for each source/drain region 30 within Region B a contact conductive layer 268 that is of a material that is absent from the source/drain region's gate 20 having one or more gate conductive layer. Contact 25 for FET 50 as shown in FIG. 23 can include contact conductive layer 268. Contact conductive layer 268 can be of a material that is absent from each gate conductive layer of gate 20 defining FET 50.

Referring further to FIG. 23, Region A can be defined as an nFET region and can have deposited n material layer 226 within gates 20 and within contact holes 264 (FIGS. 16-17, 20-22) of Region A. Further, n material layer 226 of Region A can be deposited adjacent to dielectric layer 204. Dielectric layer 204 of gate 20 can be deposited adjacently above a channel region 120 which can be defined within substrate 102. Region A as depicted in FIG. 23 can be absent p material layer 236.

Referring to Region B of the fabricated semiconductor device as shown in FIG. 23, Region B can be defined as a pFET region and can have deposited within each gate 20 of Region B p material layer 236 adjacent to dielectric layer 204. Dielectric layer 204 can be adjacent to and above channel region 120 defined in substrate 102.

In another embodiment, the depositing of a p material layer 236 as described in connection with FIG. 21 can be replaced with a depositing of an n material layer 226 and the depositing of an n material layer 226 as set forth in FIG. 23 can be replaced by a depositing of a p material layer 236. In such an embodiment, Region A as depicted in FIG. 23 can be configured as a pFET region and can include a contact conductive layer and a gate conductive layer of a common material, the common material being a p material. Region B of such an embodiment can be configured as an nFET region and can include a FET 50 having contact conductive layer 268 for a source/drain region 30 of the FET that is of a material that that is absent from the gate 20 of the FET having one or more conductive layer.

Referring to contacts 25 herein, a contact conductive layer adjacent to a source/drain region 30 can be regarded as a lower elevation contact conductive layer. A contact conductive layer can otherwise be regarded as a lower elevation contact conductive layer by having a section below a midpoint between the elevation defined between the elevation 504 (FIG. 10, 12, 23) of a top of source/drain region 30 and an elevation 506 (FIG. 10, 12, 23) of the top of gate 20.

Referring to gates 20 herein, a gate conductive layer adjacent to a gate dielectric layer 204 can be regarded as a lower elevation gate conductive layer. A gate conductive layer can otherwise be regarded as a lower elevation gate conductive layer by having a section below a midpoint between the elevation defined between the elevation 502 (FIG. 10, 12, 23) of bottom of gate 20 and an elevation 506 (FIG. 10, 12, 23) of the top of gate 20.

Each of the deposited layers as set forth herein e.g., layer 226, layer 228 layer 236, layer 238, layer 268, can be deposited using any of a variety of deposition processes, including, for example, physical vapor deposition (PVD), atomic layer deposition (ALD), chemical vapor deposition (CVD), sputtering, or other known processes, depending on the material composition of the layer.

In one example, protective mask layers as set forth herein, e.g., mask layers 212, 214, 240, 248, 254, 256, 270, 272 as set forth herein may include a material such as, for example, silicon nitride, silicon oxide, or silicon oxynitride, and may be deposited using conventional deposition processes, such as, for example, CVD or plasma-enhanced CVD (PECVD). In other examples, other mask materials may be used depending upon the materials used in semiconductor device 100. For instance, a protective mask layer, e.g., layer 212, 214, 240, 248, 254, 256, 270, 272 may be or include an organic material. For instance, flowable oxide such as, for example, a hydrogen silsesquioxane polymer, or a carbon-free silsesquioxane polymer, may be deposited by flowable chemical vapor deposition (F-CVD). In another example, a protective mask layer, e.g., layer 212, 214, 240, 248, 254, 256, 270, 272 may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB).

Removing a sacrificial polysilicon gate and a sacrificial conductive layer and material of a conductive layer, e.g., layer 226, layer 228, layer 236, layer 238, layer 268, as set forth herein can be achieved by any suitable etching process, such as dry or wet etching processing. In one example, isotropic dry etching may be used by, for example, ion beam etching, plasma etching or isotropic RIE. In another example, isotropic wet etching may also be performed using etching solutions selective to the material subject to removal.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A semiconductor device comprising:
a first field effect transistor (FET) having a source/drain region and a first gate formed on a substrate;
wherein a contact conductive layer of a contact for the source/drain region and a gate conductive layer of the first gate are of a first common conductive material,
wherein the semiconductor device includes a second FET having a source/drain region and a second gate, wherein a contact conductive layer of a contact for the source/drain region of the second FET, and a gate conductive layer of the second gate, and are of a second common conductive material.

2. The semiconductor device of claim 1, wherein the first FET is an nFET and wherein the first common conductive material is an n material.

3. The semiconductor device of claim 1, wherein the first FET is a pFET and wherein the first common conductive material is a p material.

4. The semiconductor device of claim 1, wherein a contact conductive layer of a contact for the source/drain region and a gate conductive layer of the first gate have a common thickness and are of a common deposition layer.

5. The semiconductor device of claim 1, wherein the contact conductive layer for the contact of the source/drain region of the first FET is adjacent to the source/drain region of the first FET.

6. The semiconductor device of claim 1, wherein the gate conductive layer of the first gate is adjacent to a dielectric layer of the first gate.

7. The semiconductor device of claim 1, wherein the contact conductive layer for the contact of the source/drain region of the first FET is adjacent to the source/drain region of the first FET, and wherein the gate conductive layer of the first gate is adjacent to a dielectric layer of the first gate.

8. The semiconductor device of claim 1, wherein the contact conductive layer for the contact of the source/drain region of the first FET is a lower elevation contact conductive layer, and wherein the gate conductive layer of the first gate is a lower elevation gate conductive layer.

9. (canceled)

10. (canceled)

11. A method for fabricating a semiconductor device, said method comprising:
forming for a first field effect transistor (FET) a source/drain region; and
depositing a contact conductive layer of a contact for the source/drain region and a gate conductive layer of a gate for the FET, wherein the contact conductive layer and the gate conductive layer are of a first common material, wherein the contact conductive layer and the gate conductive layer are commonly deposited, the contact conductive layer and the gate conductive layer being of a common deposition layer, and wherein the first common material is a material selected from the group consisting of nitride material and carbide material.

12. The method of claim 11, wherein the contact conductive layer and the gate conductive layer are of a common thickness.

13. (canceled)

14. The method of claim 11, wherein the first common conductive material is selected from the group consisting of an n material and a p material.

15. The method of claim 11, wherein the first gate conductive layer is adjacent to a dielectric layer of the first gate.

16. The method of claim 11, wherein the contact conductive layer is adjacent to the source/drain region of the first FET.

17. The method of claim 11, wherein the contact conductive layer is adjacent to the source/drain region of the first FET, and wherein the gate conductive layer is adjacent to a dielectric layer of the first gate.

18. The method of claim 11, wherein the contact conductive layer is a lower elevation layer for the contact of the source/drain region of the first FET, and wherein the gate conductive layer is a lower elevation gate conductive layer for the gate.

19. The method of claim 11, wherein the forming includes forming for a second FET a source/drain region, wherein the depositing includes depositing a contact conductive layer of a contact for the source/drain region of the second FET and a gate conductive layer of a gate for the second FET, wherein the contact conductive layer of a contact for the source/drain region of the second FET and the gate conductive layer of a gate for the second FET are of a second common conductive material.

20. The method of claim 11, wherein the forming includes forming for a second FET a source/drain region, wherein the depositing includes depositing a contact conductive layer of a contact for the source/drain region of the second FET and one or more gate conductive layers to form a gate for the second FET, wherein the first conductive layer of a contact for the source/drain region of the second FET includes a material that is absent from the gate for the second FET having the one or more gate conductive layers.

21. The method of claim 1, wherein the gate conductive layer of the second gate is adjacent to a dielectric layer of the second gate.

22. The method of claim 1, wherein the gate conductive layer of the second gate is a lower elevation conductive layer of the second gate.

23. The method of claim 1, wherein the second common material is selected from the group consisting of carbide material and a nitride material.

24. The method of claim 11, wherein the first common material is selected from the group consisting of TiN and TiAlC.

25. A semiconductor device comprising:
a first field effect transistor (FET) having a source/drain region and a first gate formed on a substrate;
wherein a contact conductive layer of a contact for the source/drain region and a gate conductive layer of the first gate are of a first common conductive material,
wherein the semiconductor device includes a second FET having a source/drain region and a second gate, wherein a contact conductive layer of a contact for the source/drain region of the second FET is formed of a material that is absent from the second gate.

26. The method of claim 25, wherein the gate conductive layer of the first gate is adjacent to a dielectric layer of the first gate.

27. The method of claim 25, wherein the gate conductive layer of the first gate is a lower elevation conductive layer of the first gate.

28. The method of claim 25, wherein the first common material is selected from the group consisting of carbide material and a nitride material.
